(19) United States
(12) Patent Application Publication
(10) Pub. No.: US 2008/0036487 A1
(43) Pub. Date: Feb. 14, 2008

(54) Integrated circuit wearout detection

(75) Inventors: Daryl Wayne Bradley, Willingham (GB); Jason Andrew Blome, Ann Arbor, MI (US); Scott Mahlke, Ann Arbor, MI (US)

Correspondence Address: NIXON & VANDERHYE, PC, 901 NORTH GLEBE ROAD, 11TH FLOOR, ARLINGTON, VA, 22203, US

(73) Assignees: ARM LIMITED, Cambridge (GB); UNIVERSITY OF MICHIGAN, Ann Arbor, MI (US)

(21) Appl. No.: 11/878,882

(22) Filed: Jul. 27, 2007

Related U.S. Application Data
(60) Provisional application No. 60/836,400, filed on Aug. 9, 2006.

(30) Foreign Application Priority Data
Feb. 2, 2007 (GB) 0702096.9

(51) Int. Cl. G01R 31/26

(52) U.S. Cl. 324/765

(57) ABSTRACT

An integrated circuit is provided with latency detecting circuitry for detecting signal generation latency within one or more functional circuits and in response thereto to generate a wearout response. The wearout response can take a variety of different forms such as reducing the operating frequency, increasing the operating voltage, operating task allocation within a multiprocessor system, manufacturing test binning and other wearout responses.

### BACKGROUND OF THE INVENTION

1. Field of the Invention

This invention relates to the field of integrated circuits. More particularly, this invention relates to the detection of wearout due to operation of integrated circuits.

2. Description of the Prior Art

Traditionally, microprocessors have been designed with the worst case operating conditions in mind. To this end, manufactures have employed burn in, guard bands, and speed binning to ensure that processors will meet a predefined lifetime qualification, or mean time to failure (MTTF). However, projections of current technology trends indicate that these techniques will be unlikely to satisfy reliability requirements in future technology generations [11]. As CMOS feature sizes scale to smaller dimensions, voltage scales at a much slower rate, causing dramatic increases in power and current density. Areas of high power density increase local temperatures leading to hot spots on the chip [27]. Since the most common wearout mechanisms, such as electromigration (EM), time dependent dielectric breakdown (TDDB), hot carrier injection (HCI), and negative bias threshold inversion (NBTI) are all highly dependent on temperature, power, and current density, the occurrence of wearout-related failures will become increasingly common in future technology generations. Recent studies have shown a 10% impact on signal latency in the first 3 years of operation for aggressive technologies. In order to address these concerns, new approaches to system design that address reliability at the architectural level are required.

In order to mitigate reliability concerns, architects and circuit designers typically employ either error detection or failure prediction mechanisms. Error detection is used to diagnose a failed or failing component by identifying (potentially transient) pieces of incorrect state within the system. Once an error is detected, the problem is diagnosed and corrective actions may be take. The second technique, failure prediction, supplies the system with a failure forecast allowing it to take preventative measures to avoid, or at least mitigate, the effects of device failures.

Historically, high-end server systems have relied on error detection to provide a high degree of system reliability. Error detection is typically implemented through coarse grained replication. This replication can be conducted either in space through the use of replicated hardware [31, 10], or in time by way of redundant computation [24, 22, 20, 35, 28, 16, 23, 21]. The use of redundant hardware is costly in terms of both power and area and does not significantly increase the lifetime of the processor without additional cold-spare devices, which further increases the cost of such techniques. Redundancy in time is potentially less expensive, but may only provide transient error detection without correction unless redundant hardware is readily available.

Failure prediction techniques are typically less costly to implement, however, they also face a number of challenges. One traditional approach to failure prediction is the use of canary circuits [3], which are designed to fail in advance of the circuits they are charged with protecting, thus providing an early indication that important processor structures are due to fail. Canary circuits are an efficient and generic means to predict failure, however there are a number of sensitive issues that must be addressed to deploy them effectively. The placement of these circuits is extremely important for accurate prediction, because the canary circuit must be subjected to the same operating conditions as the circuit it is meant to monitor. At the same time, it is important that these circuits do not disturb the circuits they are meant to protect, by inadvertently raising the local temperature and adversely impacting reliability lifetimes.

Recent work by Srinivasan, et al [33] proposes a novel predictive technique which monitors dynamic chip-level parameters in order to quantity the MTTF for different structures within the microprocessor. This system can then be used to swap in cold spares based on an online calculation of the expected time to failure for a given structure. This work also pioneered the idea of dynamically trading performance for reliability in order to meet a predefined lifetime qualification. Though this technique may be used to predict which structures are likely to fail in the near future, it relies on accurate analytical device wearout models and low variation in processor wearout for effective predictions.

### SUMMARY OF THE INVENTION

Viewed from one aspect the present technique provides a method of detecting wearout of an integrated circuit having at least one functional circuit, said method comprising:

detecting signal generation latency of at least one signal within a functional circuit; and

in response to said signal generation latency, triggering a wearout response.

This is a predictive technique that monitors wearout online in order to predict impending failure. Rather than aggressively deploying duplicate fault-checking structure or relying on analytical wearout models, the technique uses an early warning system that uses the symptoms of wearout to predict that failure is imminent. Wearout caused by phenomenon such as TDDB, HCI, NBTI and EM, each typically express themselves as an increasing signal propagation latency through structures prior to inducing device failure. This observation enables the uses a generic online latency sampling unit (latency detecting circuitry), referred to as a wearout detection unit or WDU, for monitoring wearout within a microprocessor core or other integrated circuit. In at least preferred embodiments, the WDU is capable of capturing the signal propagation latency for the outputs of an architectural structure. This information can then be sampled and filtered though a statistical analysis mechanism that accounts for anomalies in the sample stream (e.g. caused by phenomenon such as clock jitter, or power and temperature fluctuations). In this way, the WDU is able to identify significant changes in the latency profile for a given structure that are indicative of immediate device breakdown and then trigger one of a number of different wearout responses. The online statistical analysis allows the WDU to be self-calibrating, adapting to each structure that it monitors, making it generic enough to be reused for a variety of architectural components within a processor. In other examples simple thresholding can be used in place of statistical analysis, i.e. a determination made as to whether for a predetermined set of vectors a predetermined latency threshold should not be reached. This provides for static/offline techniques.

Whilst it would be possible for the wearout response to be triggered when wearout has actually occurred and some failure has actually taken place, other embodiments trigger the wearout response when a suitable increase in the signal generation latency occurs and before a failure due to wearout.

The detecting of signal generation latency may be done directly and in a straightforward fashion. However, it will be appreciated that latency varies considerably depending upon a wide variety of different factors and can vary from cycle to cycle, such as due to particular data values being processed or other short lived phenomena. It can also vary with temperature, current change and voltage change. In this context, some embodiments of the technique employ detecting techniques which include averaging of the signal generation latency over time to generate and averaged signal generation latency and then trigger a wearout response from the average signal generation latency so determined.

Averaging can be performed in a wide variety of different ways including generating at least a short term average and long term average and possibly including a triple smoothed exponential moving average, which is particularly well suited to use in such circumstances.

The wearout response which is triggered can take a wide variety of different forms. Cold swapping spare circuitry in place of circuitry in which imminent wearout failure has been detected is one example. Another example would be reducing the operating frequency of the integrated circuitry, such that it was operational but backed away from higher frequencies which could result in wearout failure due to excessive latency of certain signals.

Another possible wearout response would be increasing the operating voltage of the integrated circuit. This would disadvantageously tend to increase power consumption, but would tend to reduce latency and accordingly avoid a wearout failure. In the context of an integrated circuit which is operable over a range of voltages and possibly frequencies, the wearout response may be to restrict one or more of these ranges so that it no longer includes certain lower voltages or certain higher frequencies.

Modern integrated circuits typically include a plurality of processing units and mechanisms for distributing tasks amongst those units. As an example, an integrated circuit may include multiple processor cores with program execution being distributed under operating system control amongst the different processor cores. In the context of an integrated circuit including a plurality of processing units, one form of wearout response can be to redistribute task allocation between the plurality of processing units so as to reduce use of one of the processing units at least in respect of the functional unit within which wearout has been detected. As an example, within a multiprocessor integrated circuit one of the cores may indicate imminent wearout in its floating point unit and when this is signalled to the operating system, the operating system can respond by ensuring that program instructions which require use of a floating point unit are directed to a different one of the processor cores having floating point units that are not subject to imminent wearout.

Another type of wearout response is binning integrated circuits as part of manufacturing test. The latency can be detected during manufacturing test to give an indication of the margin for wearout present within the integrated circuit and the integrated circuits binned (sorted and classified) in accordance with this detection. Thus, particular integrated circuits having the highest margin and resistance against wearout could be treated as the premium product whereas functional integrated circuits with a lower margin against wearout can be differently classified and be non-premium products.

A further example of a wearout response is to target self test operations at the functional unit in which imminent wearout has been detected. Thus, in systems where high reliability is a requirement, e.g. safety critical systems, then should a particular functional unit be detected by the latency detection to be approaching a wearout condition, then additional self test operations may be focussed upon that functional unit to ensure that any failure therein is detected as soon as possible.

The latency detection circuit can take a wide variety of different forms. One particular form well suited to this use is where the detection is performed by comparing occurrence of a transition of a signal within the functional unit with occurrence of transitions in a plurality of reference signals having respective predetermined reference relative timings. Thus, the signal within a functional unit can be monitored and its transition classified as before or after each of the reference timing signals and accordingly a measure made of the latency as this relative timing varies with use and wearout.

The plurality of reference signals may be conveniently and accurately generated by a plurality taps from a delay line.

Viewed from another aspect the present invention provides an integrated circuit comprising:

at least one functional circuit;

latency detecting circuitry responsive to at least one signal within a functional circuit to detect signal generation latency; and

wearout response triggering circuitry coupled to latency detecting circuitry and responsive to said signal generation latency to trigger a wearout response.

Viewed from a further aspect the present invention provides an integrated circuit comprising:

at least one functional circuit means;

latency detecting means for detecting signal generation latency in at least one signal within a functional circuit; and

wearout response triggering means coupled to said latency detecting circuitry for triggering a wearout response in response to said signal generation latency.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 illustrates an OR1200 microprocessor core floorplan and associated characterising parameters;

FIG. 2 is a flow chart schematically illustrating the implementation and simulation of the OR1200 microprocessor core of FIG. 1;

FIG. 3 are charts illustrating the workload-dependent steady state temperature and MTTF for the OR1200 microprocessor core of FIG. 1 using a modelled ambient temperature of 333 K for Hotspot;

FIG. 4 shows graphs illustrating the reliability models correlating with wearout time;

FIG. 5a illustrates the average signal latency of an ALU result bus least significant bit measured over the lifetime of the microprocessor, FIG. 5b illustrates the distribution of the sampled latencies for that signal during the grace period of operation, and FIG. 5c illustrates the average percent increase in latency over time for all module outputs in the OR1200 microprocessor core;

FIG. 6 illustrates trend analysis of the signal latency data of FIGS. 5a, 5b and 5c;

FIG. 7 schematically illustrates the circuit design of a wearout detection unit;

FIG. 8 illustrates the variation of delay through a single inverter with temperature;

FIG. 9 illustrates a second example implementation of a wearout detection unit supplemented with the ability to track multiple module outputs;

FIG. 10 illustrates the variation of the percentage of output signals upon which the wearout detection unit is able to detect wearout with processor age;

FIG. 11 illustrates the gains in MTTF from the addition of cold spares and wearout detection units applied to various functional units with the gains being shown as cumulative and where spare modules are added in the order in which modules are expected to fail (values in parenthesis reflect the number of spares available);

FIG. 12 is a flow diagram schematically illustrating the operation of a wearout detection unit (latency detecting circuitry) in monitoring multiple signals within the functional circuit;

FIG. 13 lists a series of example wearout responses;

FIG. 14 illustrates a multiprocessor system in which task allocation may be adjusted to avoid a functional unit subject to imminent wearout; and

FIG. 15 is a diagram schematically illustrating an integrated circuit which may be subject to binning at manufacturer in dependence upon wearout properties detected.

### DESCRIPTION OF THE PREFERRED EMBODIMENTS

### Background

In order to better understand the physical phenomenon that cause wearout and why technology scaling has such a dramatic impact on lifetime reliability, we briefly discuss a subset of the wearout mechanisms that plague modern integrated circuit designs (e.g. microprocessor designs). This section presents industry-standard theoretical models for each wearout mechanism and discusses how these mechanisms affect circuit-level timing within the design.

### Electromigration (EM)

EM is a physical phenomenon that causes the mass transport of metal within semiconductor interconnects. As electrons flow through the interconnect, momentum is exchanged when they collide with metal ions. This pushes metal ions in the direction of electron flow and, at high current densities, results in the formation of voids (regions of metal depletion) and hillocks (regions of metal deposition) in the conductor metal [13].

The model of electromigration that we employ is based on a version of Black's equation found in [5] and is consistent with recent literature [19, 32]:

MTTF_{EM}∝(J−J_{crit})⁻ⁿe^{(E}^{ₐ}^{/kT)} (1)

where,

### J=current density (J>>Jcrit)

### J_{crit}, threshold current density at which EM begins

n=1.1, material dependent constant

### Eₐ=0.9 eV (activation energy)

k=Boltzmann's constant

### T=temperature

Studies have shown that the progression of EM over time can be separated into two distinct phases. During the first phase, sometimes referred to as the incubation period, interconnect characteristics remain relatively unchanged as void formations slowly increase in size. Once a critical void size is achieved, the second phase, the catastrophic failure phase is entered, characterized by a sharp increase in interconnect resistance [17, 13].

This sharp increase in interconnect resistance can be related to interconnect delay using the Elmore delay equation [15,4], arguably the most widely used interconnect delay model. This model describes how delay through interconnects are related to various parameters including: driver impedance, load capacitance, geometry, etc.:

$$Delay = A \cdot {r}_{d} {c}_{a} l w + B \cdot {r}_{d} {c}_{f} l + C \cdot {r}_{d} {c}_{f} + D \cdot \frac{{rc}_{a} {l}^{2}}{2} + E \cdot \frac{{rc}_{f} {l}^{2}}{2 w} + F \cdot \frac{{rlc}_{l}}{w} \\ Delay = κ + r \cdot γ \\ Δ Delay ∝ Δ r \cdot γ \qquad ( 2 )$$

where,
r is the resistance of the interconnect wire
κ incorporates all terms in (2) that are independent of r
γ incorporates all terms in (2) that are dependent on r

Empirical studies focusing on interconnects spanning a wide range of process technologies have correlated a sharp rise in resistance as the mass transport of metal begins to inhibit the movement of charge. Coupling this phenomenon with Equation 2, it follows that EM can be modelled as an increasing interconnect delay. Further, as technology scales, smaller wire geometries, coupled with increasing current densities will dramatically accelerate the effects of EM.

### Time Dependent Dielectric Breakdown (TDDB)

TDDB, also known as gate oxide breakdown, is caused by the formation of a conductive path through the gate oxide. TDDB exhibits two distinct failure modes, namely soft and hard breakdown [14, 8, 30]. The widely accepted Klein/Solomon model [30] of TDDB characterizes oxide wearout as a multistage event with a prolonged wearout period (trap generation) during which charge traps are formed within the oxide. This is followed by a partial discharge event (soft breakdown) triggered by locally high current densities due to the accumulation of charge traps. Typically, in thinner oxides, a series of multiple soft breakdowns eventually leads to a catastrophic thermal breakdown of the dielectric (hard breakdown).

The rate of failure due to TDDB is dependent on many factors, the most significant being oxide thickness, operating voltage, and temperature. This work uses the empirical model described in [32] which is based on experimental data collected at IBM [37]:

$${MTTF}_{TDDB} ∝ {( \frac{1}{V} )}^{( a - bT )} {e}^{\frac{( X + \frac{Y}{T} + ZT )}{kT}} \qquad ( 3 )$$

where,
v=operating voltage

### T=temperature

k=Boltzmann's constant
a, b, X, Y, and Z are all fitting parameters based on [37]

Research has shown that TDDB has a detrimental impact on circuit performance. As the gate oxide wears down, the combined effects of increased leakage current and shifting current-voltage curves results in devices with slower response times [8]. Further, the ultra-thin oxides projected in future technology generations, will make devices increasingly susceptible to TDDB.

### Negative Bias Temperature Instability (NBTI)

NBTI occurs predominantly in PFET devices and causes the gate to become negatively biased with respect to the source and the drain, leading to an accumulation of positive charge within the gate oxide. The main effect of NBTI is an increase in the threshold voltage of the transistor, slowing down the performance of the gate. The model used in this work is from work at IBM [39]:

$${MTTF}_{NBTI} ∝ {( ( \begin{matrix}ln ( \frac{A}{1 + 2 {e}^{β / kT}} ) - \\ ln ( \frac{A}{1 + 2 {e}^{β / kT}} - C )\end{matrix} ) * \frac{T}{{e}^{- D / kT}} )}^{1 / β} \qquad ( 4 )$$

where,

### A,B,C,D and β are fitting parameters derived in [39]

k=Boltzmann's constant

NBTI causes failure by shifting the threshold voltage of the device to the point where signal propagation delay exceeds the clock cycle time. Since the shift in threshold voltage due to NBTI is largely a function of temperature, the effects of this wearout mechanism, will become more pronounced in the coming technology generations.

### Discussion

Though this is not an exhaustive list of all potential wearout mechanisms, it does illustrate a representative set of potential wearout mechanisms and the ways in which feature size scaling will affect the reliability of future microprocessors. Most importantly, the physical impact of all these wearout phenomenon is increased device delay until ultimate failure. Wearout mechanisms not discussed here, such as hot carrier injection and stress migration, have been shown to be similarly dependent on current density and temperature and are expected to also negatively affect device delay.

### Wearout Simulation Infrastructure and Analysis

This section describes the infrastructure developed to simulate the effects of wearout over time and details the wearout characteristics of an embedded processor (as one example of an integrated circuit). It begins by describing the microprocessor core studied in this work, along with the synthesis flow used for its implementation. This is followed by a description of the approach used to calculate MTTF values for structures within the design. Finally, the model used to correlate wearout with time is presented along with a statistical analysis of the impact of wearout on signal propagation latency.

### Microprocessor Implementation

The testbed used to conduct wearout experiments was a Verilog model of the OpenRISC 1200 (OR1200) CPU core [1]. The OR1200 is an open-source, embedded-style, 32-bit, Harvard architecture that implements the OR-BIS32 instruction set. The microprocessor contains a single-issue, 5-stage pipeline, with direct mapped 8 KB instruction and data caches and virtual memory support. This microprocessor core has been used in a number of commercial products and is capable of running the μClinux operating system.

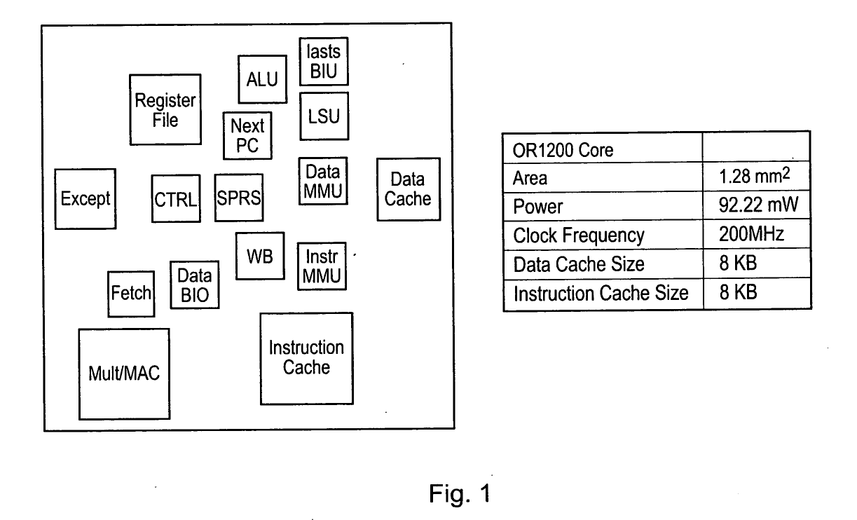

The OR 1200 core was synthesized using Synopsys Design Compiler with an Artisan cell library characterized for a 130 nm IBM process with a clock period of 5 ns (200 MHz). Cadence First Encounter was used to con-duct floorplanning, cell placement, clock tree synthesis, and routing. This design flow provided accurate timing information (cell and interconnect delays), and circuit parasitics (resistance and capacitance values) for the entire OR 1200 core. The floorplan along with several salient characteristics of the implementation is shown in FIG. 1.

The final layout of the OR1200 includes a guard band of 100 ps slack time and consists of roughly 24,000 logic cells.

### Mean Time to Failure Calculation

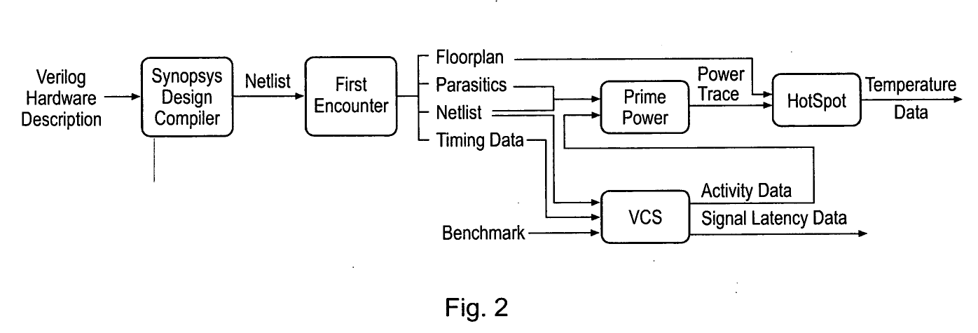

In this work, the MTTF values for design elements (logic cells and wires) within the microprocessor core were calculated using the equations modelling EM, TDDB, and NBTI presented above. These MTTF calculations required two parameters, activity and local temperature, for each design element. The activity data was generated by simulating the execution of a benchmark on the core using Synopsys VCS (Five benchmarks were chosen for this study to represent a range of computational behaviour for embedded systems: dhrystone—a synthetic integer benchmark; g721 encode and rawcaudio from the MediaBench suite; rc4—an encryption algorithm; and sobel—an image edge detection algorithm). This activity information, along with the parasitic data generated during placement and routing, was then used by Synopsys PrimePower to generate a per-benchmark power trace. The power trace and floorplan were in turn processed by HotSpot [27], a block level temperature analysis tool, to produce a dynamic temperature trace and a steady state temperature (per benchmark) for each structure within the design. A flowchart detailing this process is shown in FIG. 2.

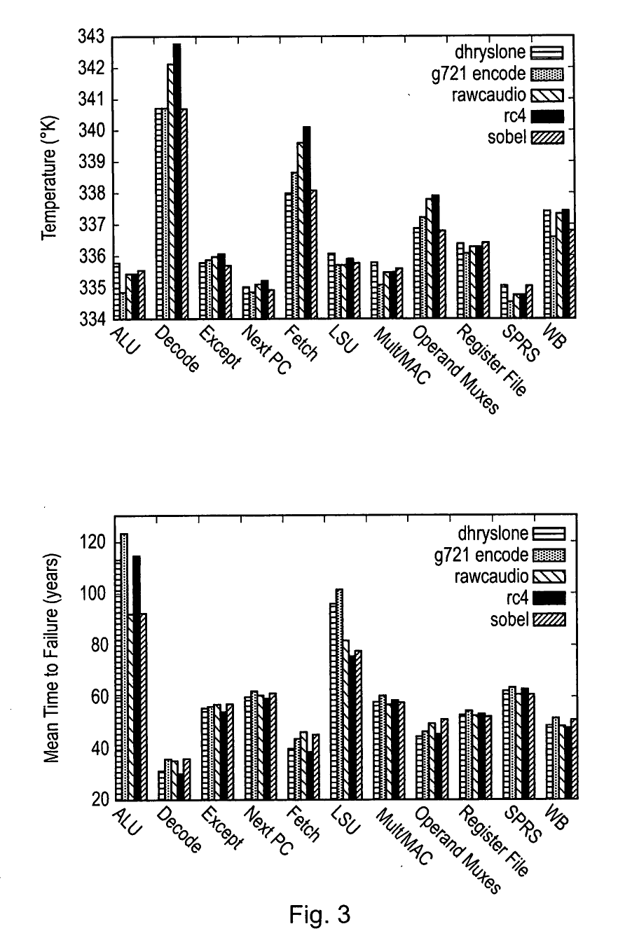

Once the per-benchmark activity and temperature data were derived, the MTTF for each wire within the design was calculated using Equation 1 for EM, and the MTTF for each logic cell was calculated using Equations 3 and 4 for TDDB and NBTI, respectively. This computation was repeated for each benchmark. The MTTF values were then normalized to the worst case (minimum) MTTF across all benchmarks, resulting in a relative wearout factor (RWF) for each design element. A per-module MTTF was determined by identifying the minimum MTTF across all design elements within each top-level module of the OR1200 core. FIG. 3 presents the steady state temperatures and MTTF values of different structures within the CPU core for the five benchmarks.

FIG. 3 highlights the correlation between temperature and MTTF. Structures with the highest temperatures tended to have the smallest MTTF, meaning that they were most likely to wearout first. For example, the decode unit, with a maximum temperature about 30 K higher than any other structure on the chip, would likely be the first structure to fail. Somewhat surprisingly, the ALU had a relatively low temperature, resulting in a long MTTF. Less than 50% of dynamic instructions (across most benchmarks) exercised the ALU, and furthermore, about 20% of the instructions that actually required the ALU were simple logic operations and not computationally intensive additions or subtractions, resulting in relatively low utilization and ultimately lower temperatures. It is important to note that although this work focuses on a simplified CPU model, the proposed WDU is not coupled to a particular microprocessor design or implementation, but rather relies upon the general circuit-level trends suggested by simulations. In fact, a more aggressive, high performance microprocessor would likely have more dramatic hotspots, which would only serve to exaggerate the trends that motivate the WDU design presented in this work.

### Wearout Simulation

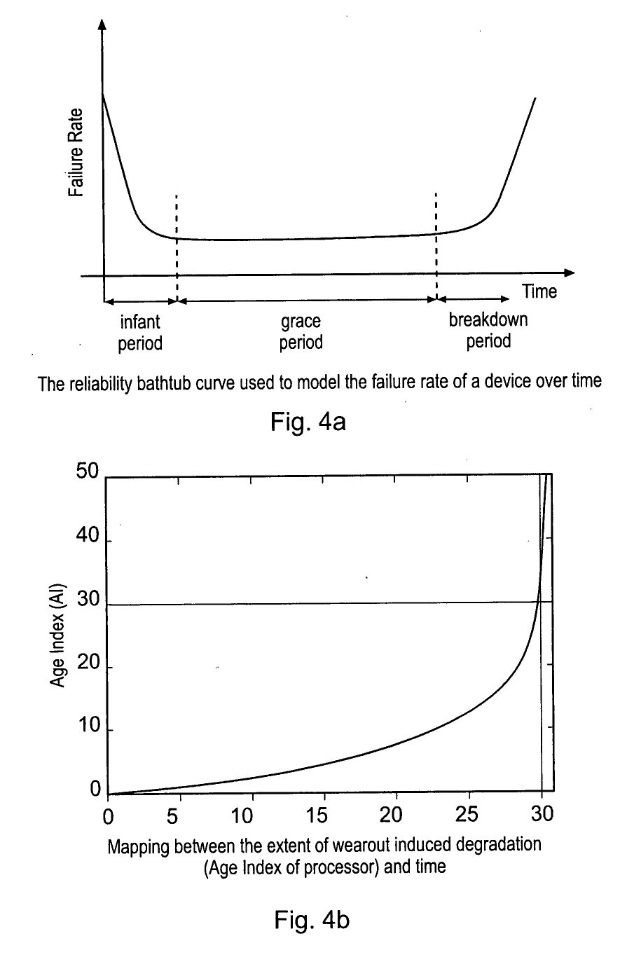

As shown above, wearout phenomena have a significant impact on circuit-level timing. In order to simulate this effect, we model wearout as a rise in interconnect delay across wires and an increase in logic cell response time. We correlate these increases in propagation latency to processor age using the widely accepted reliability bathtub curve [26], depicted in FIG. 4a. The bathtub curve is used to depict the failure rate for devices within a population over time.

The bathtub curve consists of three distinct regions, the infant period, the grace period, and the breakdown period. The infant period is characterized by a significant but decreasing rate of failures as weak/defective devices fail soon after manufacture. The grace period, characterized by a small but slowly increasing failure rate, constitutes the majority of a device's lifespan, and comes to an end near to the MTTF of the device. At this point, the breakdown period is entered, where the effects of wearout become more prominent. As these effects gain momentum, the failure rate increases dramatically. The WDU proposed herein is used to detect this period and safeguard against failures.

In order to quantify the effects of wearout, a model was derived correlating the age of a microprocessor to the maximum percentage increase in latency experienced by any logic cell or wire. This time-dependent worst case percentage increase in latency is referred to as the Age Index (AI). In other words, the AI represents the decrease in performance for the most degraded logic cell or wire across the entire processor at given point in time. FIG. 4b plots the mapping from the AI to time used herein. In this model, it is assumed that a worst case increase of 30% in cell response time or interconnect delay coincides with a 30 year MTTF (A mean lifetime of 30 years is assumed for the design, which is consistent with the available data in published literature [2]. Realistic design targets are likely lower for mainstream desktop and embedded processors. Assuming a smaller lifetime would only scale the time axis of the results and not affect the observations or conclusions). To support the use of this model, we rely on the combination of two known properties of wearout. First, as shown in Section 2, wearout causes an increase in signal propagation latency. Second, as demonstrated in many empirical studies [17, 13, 8], wearout mechanisms begin slowly over time, having little effect on circuits during the infant and grace periods and then progress rapidly over time during the breakdown period. The combination of these two phenomena imply that the breakdown period is characterized by a rapid increase in signal propagation latency leading up to device failure.

To simulate the effects of wearout using an increase in signal propagation latency, the increase in latency for each logic cell and wire is determined using their respective RWFs and the processor's AI. To simulate the effects of process variation and the fact that some areas of the design are more robust than others, we also apply a Gaussian random variable with a mean of 1 and a standard deviation of 5%. The change in delay due to wearout for each logic cell and wire within the design is then calculated as shown in Equation 5. Note that the RWF of a device/wire and its original delay are both static values while the AI increases over time (see FIG. 4b). This results in escalating delays as the device ages.

Δdelay=(original delay)×(RWF)×(AI)×(random variable) (5)

Wearout-dependent delay data for each individual design element was collected and used to model the latency behaviour of entire paths through higher-level architectural structures. Accurate modelling of these path latencies was done with a framework developed for interacting with the Synopsys VCS simulator. Wearout dependent delay information (Δdelay) for each cell and wire was annotated onto the design netlist and custom signal monitoring handlers were registered to measure the propagation delay through design modules. The signal monitors captured this latency information into a database that furnished random samples for the statistical analysis described below.

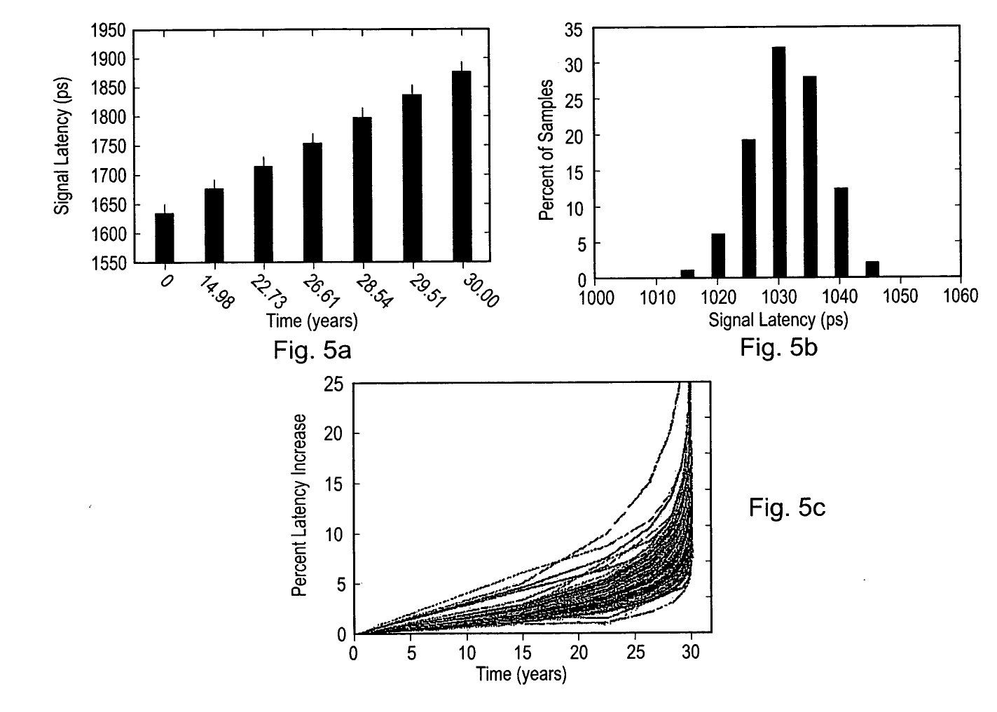

FIG. 5a plots the average of recorded sample mean latency values for the least significant bit of the ALU result bus (obtained while the processor is running the five benchmarks). The error bars bound the range of observed latencies for this experiment. One may notice the data suggests that there does not exist much variation in the output latency. However, the lack of variation in this plot is because the averaging of sample mean latencies acts as a low pass filter. Sample mean values were averaged in this experiment to mimic the hardware based sampling methodology described in the following section.

FIG. 5b shows the distribution of the observed latencies on the least significant bit of the ALU result bus throughout the grace period. Note that the majority of the sample points lie within a tightly bounded region falling rather sharply toward the tails.

Lastly, FIG. 5c plots the percent increase in latencies for all top level module output signals. This figure demonstrates that most signals experience a sharply increasing latency when the breakdown period is entered, at roughly 30 years. The following section discuss how this trend is used to detect the onset of the breakdown period.

### Wearout Detection Unit

In this section, we use the latency trends demonstrated in Section 3 to design a generic, self-calibrating wearout detection unit (WDU) that can be used to monitor a variety of processor structures and predict their likely failure.

An introduction to the trend analysis technique used in the WDU design is presented first. This is followed by details of the design and implementation of the WDU. Next a brief description of dynamic environmental variations, such as clock jitter and power/temperature fluctuations, is provided, as well as an analysis of how these variations may affect the operation of the WDU. Finally, the details of integrating a WDU into the microprocessor pipeline are discussed.

The area and power overhead of the WDU, its accuracy in detecting wearout, and the increase in processor lifetime that can be achieved by augmenting a design with WDUs and cold spare structures, are discussed following this.

### Trend Analysis

FIG. 5c demonstrates that the output signals from most modules experience a sharp rise in propagation latency as the microprocessor approaches the breakdown period. In order to capitalize on this trend of divergence from the signal propagation latencies observed during the infant and grace periods of the microprocessor's lifetime, TRIX (triple-smoothed exponential moving average) [34] is used, this is a trend analysis technique used to measure momentum in financial markets. TRIX analysis relies on the composition of three calculations of an exponential moving average (EMA) [9]. The EMA is calculated by combining a percentage of the current sample value with an inverse percentage of the previous EMA, causing the weight of older sample values to decay exponentially over time. The calculation of EMA is given as:

EMA=α×sample+(1−α)EMAₚᵣₑᵥᵢₒᵤₛ

The use of TRIX rather than the EMA provides two significant benefits. First, TRIX provides an effective filter of noise within the data stream because the composed applications of the EMA act as a filter, smoothing out aberrant data points that may be caused by dynamic variation, such as temperature or power fluctuations. Second, the TRIX value tends to provide a better leading indicator of sample trends. The equations for computing the TRIX value are:

EMA₁=α(sample−EMA₁ₚᵣₑᵥᵢₒᵤₛ)+EMA₁ₚᵣₑᵥᵢₒᵤₛ

EMA₂=α(EMA₁−EMA₂ₚᵣₑᵥᵢₒᵤₛ)+EMA₂ₚᵣₑᵥᵢₒᵤₛ

TRIX=α(EMA₂−TRIXₚᵣₑᵥᵢₒᵤₛ)+TRIXₚᵣₑᵥᵢₒᵤₛ

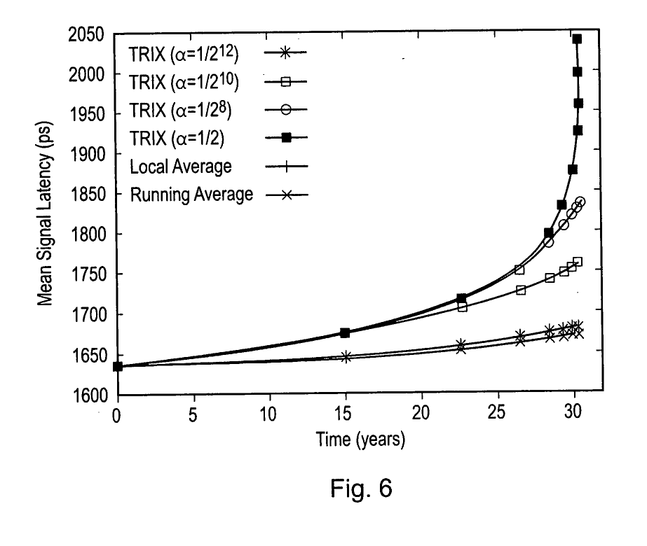

TRIX calculation is recursive and parameterized by the weight, α, applied to previous TRIX calculations. The WDU discussed below uses the calculation of two TRIX values using different weights to determine the divergence of trends in the observed signal latency. FIG. 6 shows the effect of different α values on the TRIX analysis of the ALU output signal latency samples from FIG. 5a. FIG. 6 demonstrates the TRIX calculations for four different a values as well as the long-term running average and local average of signal latency samples over the lifetime of the microprocessor. This data demonstrates that TRIX calculation using α=½¹² provides an accurate estimate of the running average sample latency over the lifetime of the chip, and does so without the overhead of maintaining a large history. Further, this figure shows that a TRIX calculation with α=½ provides a good indicator of the local sample latency for a given point in the microprocessor's lifetime.

Below there is discussed how TRIX calculations using these particular α values can be leveraged to determine the onset of the breakdown period.

### Wearout Detection Unit

The WDU discussed herein uses the calculation of two TRIX values which diverge significantly when the microprocessor enters the breakdown period. The first TRIX calculation, TRIXₗ, is used to track the local latency trend by weighting recent samples heavily. The second TRIX calculation, TRIX_{g}, is used to track the global latency trends, placing significantly more emphasis on the latency history.

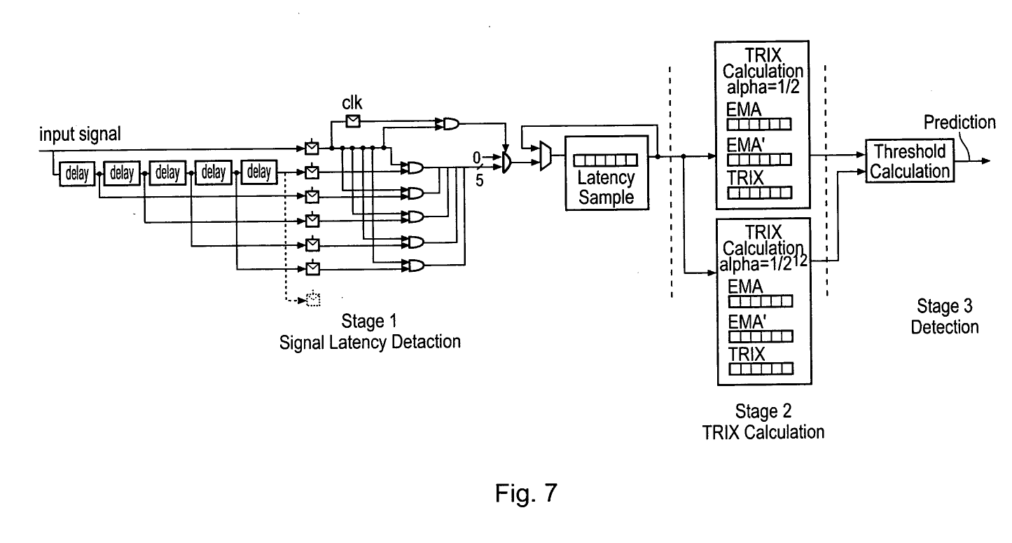

A schematic diagram of the WDU is shown in FIG. 7. The WDU consists of three distinct stages. The first stage generates an approximation of the propagation latency through a module (for a given output) by measuring the amount of slack that exists between when the signal stabilizes and the next positive edge of the clock. The delay line provides a plurality of taps giving a sequence of delayed transitions that can be compared to the transition being monitored. The taps each provide a reference relative timing against which latency can be measured. The first stage accumulates a sample of 1024 latency measurements and uses this sum as a point estimate for the mean latency. The second stage of the WDU then uses this point estimate of the mean to calculate new values for TRIXₗ and TRIX_{g}. In the final stage, the percent difference between TRIXₗ and TRIX_{g} is computed and compared against a threshold value to determine whether or not the microprocessor has entered the breakdown period (i.e. has worn out or will soon wear out).

### Stage 1: Signal Latency Detection

The purpose of the first stage is to obtain a point estimate of the mean propagation latency for a given output signal. The signal being monitored is tapped off from the functional unit in which it is used and fed into the first stage of the WDU and is subjected to a series of delay buffers. Each delay buffer in this series feeds one bit in a vector of registers such that the signal arrival time at each register in this vector is monotonically increasing. At the positive edge of the clock, some of these registers will capture the correct value of the module output, while others will store an incorrect value (the previous value on the output line). This situation arises because the addition of delay buffers causes the output signal to arrive after the clock edge for a subset of these registers. The value stored at each of the registers is then compared with a copy of the correct output value. This pair-wise comparison produces a bit vector that represents the propagation delay of the path exercised by the module output being monitored. As the signal latency increases (i.e. wearout progresses) fewer comparisons will succeed as more and more signals arrive late to their respective registers.

One important consideration in designing Stage 1 of the WDU is the length of the buffer chain used to measure slack time. The amount of delay introduced must be sufficient to cause at least some registers within the WDU to latch incorrect values, each time a module output transitions, in order to generate useful delay profiles. Depending on the particular path being exercised this delay could be substantial. However, as we demonstrate later, the area required by this delay chain (even in the worst case) does not significantly impact the overall area of the WDU

### Stage 2: TRIX Calculation

The propagation latency for a signal is dependent upon 1) the module inputs and 2) the path taken for signal propagation. Therefore, the second stage of the WDU depends upon an initial averaging filter to capture a representative sample of the latency for a given output signal. For this example 1024 signal transition latencies are accumulated in stage 1 before the sample value is passed on to stage 2.

Next, TRIXₗ and TRIX_{g} are calculated using α values of ½ and ½¹² respectively. It is important to note that the value of α is dependent on the sample rate and sample period. Herein it is assumed a sample rate of three to five samples per day is used over an expected 30 year lifetime. Also, the long incubation periods for many of the common wearout mechanisms require that the computed TRIX values are routinely saved into a small area of non-volatile storage, such as flash memory.

Since the three TRIX calculations are identical, the impact of Stage 2 on both area and power can be minimized by spanning the calculation of the TRIX values over multiple cycles and only synthesizing a single instance of the TRIX calculation hardware.

### Stage 3: Detection

The final stage of the WDU receives TRIXₗ and TRIX_{g} values from the previous stage and is responsible for predicting a wearout if the difference between these two values exceeds a given threshold. The simulations conducted indicate that a 10% difference between TRIXₗ and TRIX_{g} is almost universally indicative of the microprocessor entering the breakdown period and therefore can be used as the threshold for triggering a wearout response. Computing this difference of 10% in the hardware is typically a costly affair, and we get around this problem by doing an approximation of percentage increase using shift operations: shift by 4 gives 6.25% of a value, shift by 5 gives 3.125%; and adding both of these together gives 9.375%, which is a good enough estimate for computing 10% of a value.

### Dynamic Variations

Dynamic environmental variations such as temperature spikes, power surges, and clock jitter can each have an impact on circuit-level timing, potentially affecting the operation of the WDU. Below are discussed some of the sources of dynamic variation and their impact on the WDU's efficacy.

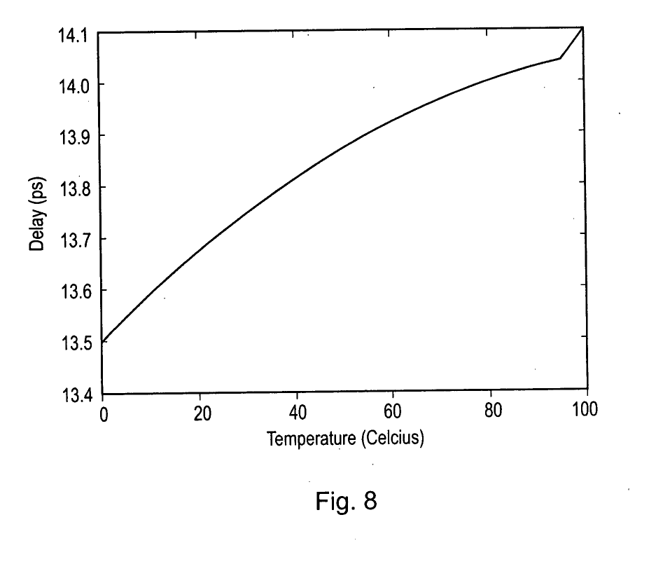

Temperature is a well known factor in calculating device delay, where higher temperatures typically increase the response time for logic cells. FIG. 8 demonstrates the increase in response time for a single inverter (inventor model was taken from the IBM 130 nm library and simulated using HSPICE) over a wide range of temperatures. This figure shows that over an interval of 100° C., the increase in response time amounts to approximately 4.4%.

Another source of variation is clock jitter. In general, there are three types of jitter: absolute jitter, period jitter, and cycle-to-cycle jitter. Of these, cycle-to-cycle jitter is the only form of jitter that may potentially affect the WDU. Cycle-to-cycle jitter is defined as the difference in length between any two adjacent clock periods and may be both positive (cycle 2 longer than cycle 1) or negative (cycle 2 shorter than cycle 1). Statistically, jitter measurements exhibit a random distribution with a mean value approaching 0[38].

In general, the sampling techniques employed by the WDU should be sufficient to smooth out the effects of dynamic variation described here. For example, a conservative, linear scaling of temperature effects on the single inverter delay to a 4.4% increase in module output delay does not present a sufficient magnitude of variance to overcome the 10% threshold required for the WDU to predict failure. Also, because the expected variation due to both clock jitter and temperature will exhibit a mean value of 0 (i.e. temperature is expected to fluctuate both above and below the mean value), statistical sampling of latency values should minimize the impact of these variations. To further this point, since the TRIX calculation acts as a three-phase low-pass filter, the worst case dynamic variations would need to cause latency samples to exceed the stored TRIXg value by more than 10% over the course of more than 12 successive sample periods, corresponding to over four days of operation.

### System Integration

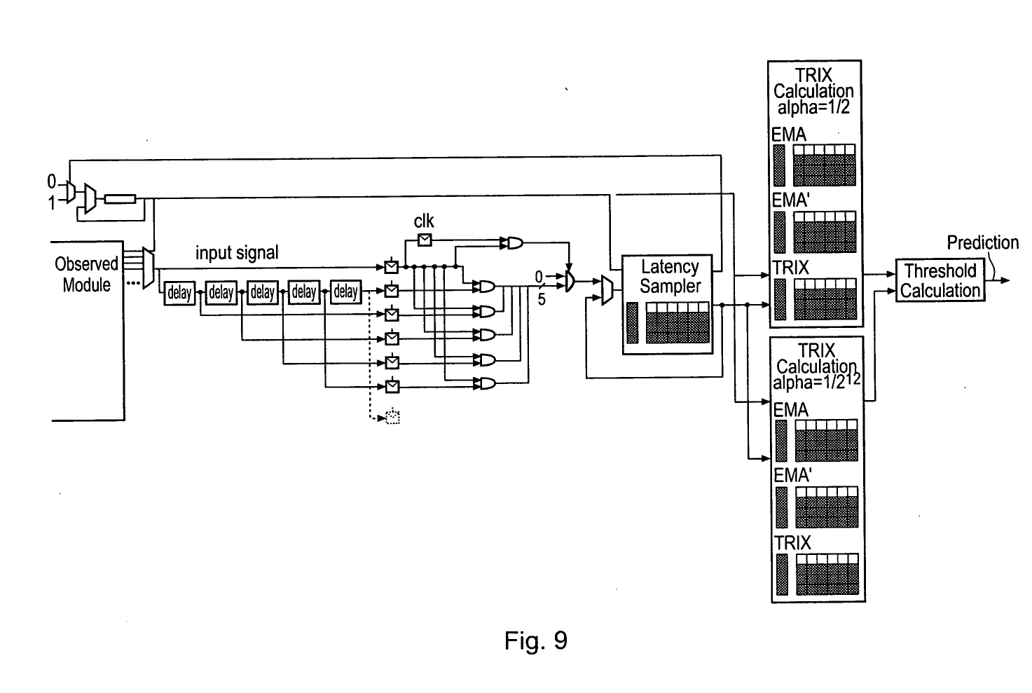

The above discussed the operation of the WDU in isolation as it monitored a single module output for an increase in signal latency. The section below discusses the necessary hardware for monitoring multiple output signals, and how the WDU can be integrated into a microprocessor to facilitate the swapping of cold spare hardware structures. FIG. 9 shows a modified version of the WDU augmented with hardware for monitoring multiple output signals.

In order to monitor multiple output signals from a module, modest hardware modifications are necessary. First, a round robin arbiter is needed to systematically cycle through the output signals from the module. This can be done with a multiplexer controlled by a wrap-around counter proportional in size to the number of signals being monitored. The counter is incremented each time Stage 2 of the WDU updates the TRIXₗ value (1024 transition events on a single output). The counter can also serve as the read/write address for a small cache which stores the TRIXₗ and TRIX_{g} value associated with each output. Once the WDU has been supplemented with this hardware, it may be used to monitor multiple output signals, significantly increasing its efficacy since observing sharp increases in latency on a single output signal is sufficient to conclude that the structure as a whole is likely to fail. Multiple signals with a functional unit may be monitored. This behaviour is analyzed below.

Given that any design augmented with a WDU has a reliable means of detecting when individual modules are worn out (ALU, LOAD/STORE, etc), the use of cold spares can be employed to extend a system's operating life. An efficient approach to enhancing reliability with minimal overhead would be to analytically determine the structures most likely to fail and only place WDUs at the outputs of the most susceptible structures. As the modules age, the WDU could indicate when to swap in a cold spare device in order to avoid catastrophic failure. The section below evaluates the potential gain in processor lifetime as a function of the area overhead for adding these devices.

| | WDU (1 Signal) | WDU (8 Signals) | OR1200 Core |
|---|---|---|---|
| Area (mm²) | 0.014 | 0.057 | 1.280 |
| Power (mW) | 1.15 | 8.02 | 92.22 |

### Table 1: Area and power synthesis results for two implementations of the WDU. The first implementation is designed to monitor only a single signal, while the second is capable of monitoring up to eight signals.

### Wearout Detection Unit Evaluation

Below are discussed area and power consumption statistics for two implementations of the WDU. In addition, we evaluate the ability of the WDU to detect the onset of the breakdown period is evaluated. Lastly, a cost benefit analysis for augmenting the OR1200 core with multiple WDU and cold spare structures is presented.

Table 1 displays the area and power consumption numbers for two WDU designs. The first implementation is a WDU designed to monitor only a single output signal, while the second implementation is designed to monitor up to eight different output signals for a given module (the justification for monitoring of only a small number of signals per module is discussed later in this section). This table shows that a typical WDU consumes only about 0.05 mm² (excluding the non-volatile storage) and that adding a single WDU to monitor up to eight output signals increases the overall CPU area by only about 4.45%. The power consumption for the WDU is estimated by Synopsys Design Compiler to be 8.02 mW, compared to an estimate of about 92.22 mW for the entire OR 1200 core. One should note even though the power consumption of the WDU is appreciably high, it amounts to a negligible energy consumption because of its infrequent use (about four times in a usage day).

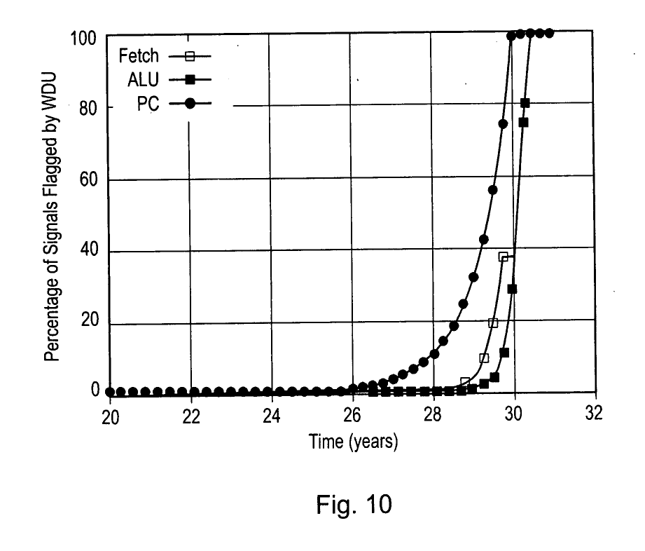

In order to assess the merits of the prediction scheme, a WDU monitoring three different structures within the OR1200 core across the five embedded benchmarks was simulated. FIG. 10 presents the percentage of output signals, for each module, that the WDU detected entering the breakdown period over the course of the microprocessor's life. This data demonstrates that the WDU is consistently able to identify at least a small percentage of output signals for each module as having experienced severe degradation just as the microprocessor is entering the breakdown region of the bathtub curve. As demonstrated in FIG. 4b, the breakdown period corresponds with the 30 year age index (AI) in the simulations. This implies that the WDU is unlikely to allow any architectural module to enter the breakdown region unnoticed.

Though FIG. 10 demonstrates that the WDU is apt at identifying the beginning of the breakdown period for at least a small fraction of signals on each module, it also demonstrates some variance in these results. For example, nearly 20% of the signals on the PC module are flagged as entering the breakdown period about 1.5 years early.

Similarly, 66% of the signals on the ALU are flagged about 0.5 years early. In general, 100% of the signals for all modules were marked as entering the wearout period within 0.33 of a year from the beginning of the breakdown period. Since the WDU attached to each of the modules was able to identify more than 75% of the signals as entering the breakdown period with 0.25 years of the 30 year AI, it is clear that the WDU need not monitor all output signals for each module.

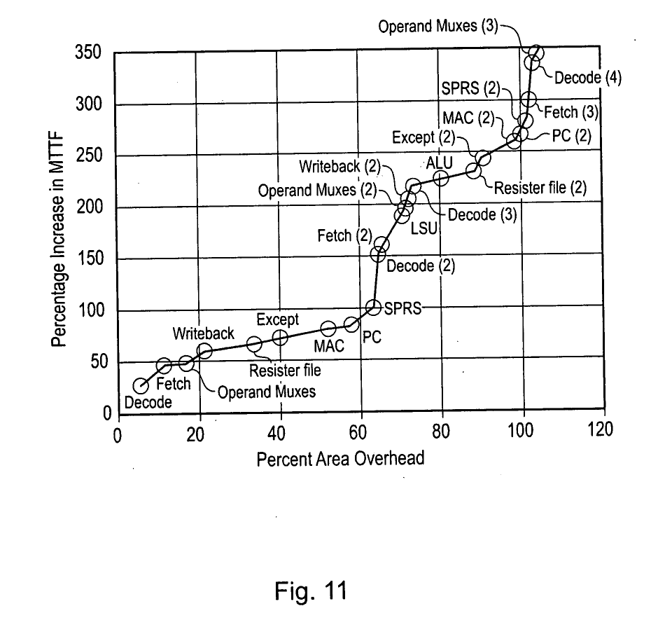

FIG. 11 illustrates the improvements in overall processor MTTF that can be achieved by attaching WDUs to different architectural units and employing cold spare structures. This data was generated by sorting the structures within the OR 1200 CPU by MTTF and provisioning redundant cold spares accordingly. Modules with the shortest expected lifetimes were allocated the most spares and modules with long MTTFs were allotted spares only when they began influencing processor MTTF. The area overhead presented here includes both the area for the WDU (one per structure) and the redundant backups (scales with the number of spares that are specified next to the module name in parenthesis in FIG. 11).

The data shown in FIG. 11 demonstrates that by strategically targeting those structures which are most likely to fail, the MTTF for the microprocessor can be significantly extended. In exchange for a 5.6% increase in area, the MTTF can be increased by more than 26.2%. Further, nearly a 100% increase in MTTF can be gained for about 64% in area. It is also interesting to note that protecting structures other than the decode and fetch unit tend to yield diminishing returns because other modules already possess sufficiently large MTTFs that the nominal gains possible from allocating spares cannot offset their respective area overheads. Additionally, note that given their respective MTTFs, the decode unit would be replicated twice before one need to worry about the status of the ALU.

### Related Work

Issues in technology scaling and process variation have raised concerns for reliability in future microprocessor generations. Recent research work has attempted to diagnose and, in some cases, reconfigure the processing core to increase operational lifetime. Below there is discussed this related work.

As mentioned above, much of the research into failure detection relies upon redundancy, either in time or space. One such example of hardware redundancy is DIVA [6] which targets soft error detection and online correction. It strives to provide a low cost alternative to the full scale replication employed by traditional techniques like triple-modular redundancy. The system utilizes a simple in-order core to monitor the execution from a large high performance superscalar processor. The smaller checker core recomputes instructions before they commit and initiates a pipeline flush within the main processor whenever it detects an incorrect computation. Although this technique proves useful in certain contexts, the second microprocessor requires significant design/verification effort to build and incurs additional area overhead.

Bower el al. [12] extends the DIVA work by presenting a method for detecting and diagnosing hard failures using a DIVA checker. The proposed technique relies on maintaining counters for major architectural structures in the main microprocessor and associating every instance of incorrect execution detected by the DIVA checker to a particular structure. When the number of faults attributed to a particular unit exceeds a predefined threshold it is deemed faulty and decommissioned. The system is then reconfigured and in the presence of cold spares can extend the useful life of the processor. Related work by Shivakumar et al. [25] argues that even without additional spares the existing redundancy within modern processors can be exploited to tolerate defects and increase yield through reconfiguration.

Research by Vijaykumar [16, 35] at Purdue, and similar work by Falsafi [20, 28], attempts to exploit the redundant, and often idle, resources of a high end superscalar processor to enhance reliability by utilizing these extra units to verify computations during periods of low resource demand. This technique represents an example of the time redundant computation alluded to in Section 1. It uses work at NCSU by the Slipstream group [24,21] on simultaneous redundant multithreading as well as earlier work on instruction reuse [29]. ReStore [36] is yet another variation on this theme which couples time redundancy with symptom detection to manage the adverse effects of redundant computation by triggering replication only when the probability of an error is high.

Srinivasan et al. have also been very active in promoting the need for robust designs that can withstand the wide variety of reliability challenges on the horizon [33]. Their work attempts to accurately model the MTTF of a device over its operating lifetime, facilitating the intelligent application of techniques like dynamic voltage and/or frequency scaling to meet reliability goals. Although some common physical models are shared in common, the focus of the present technique is not to guarantee that designs can achieve any particular reliability goal but rather to enable a design to recognize behaviour that is symptomatic of wearout induced breakdown allowing it to react accordingly.

Analyzing circuit timing in order to self-tune processor clock frequencies and voltages is a well studied area. Kehl [18] discusses a technique for re-timing circuits based on the amount of cycle-to-cycle slack existing on worst-case latency paths. The technique presented requires offline testing involving a set of stored test vectors in order to tune the clock frequency. Although the proposed circuit design is similar in nature to the WDU, it only examines the small period of time preceding a clock edge and is only concerned with worst case timing estimation, whereas the WDU employs sampling over a larger time span in order to conduct average case timing analysis. Similarly, Razor [7] is a technique for detecting timing violations using time-delayed redundant latches to determine if operating voltages can be safely lowered. Again, this work studies only worst-case latencies for signals arriving very close to the clock edge.

### CONCLUSION

In the above there is described online wearout detection unit to predict the failure of architectural structures within microprocessor cores. This unit uses the symptoms of wearout to predict imminent failure. This solution seeks to utilize signal latency information for wearout detection and failure prediction. To investigate the design of the WDU, accelerated wearout experiments are presented above on the OpenRISC 1200 embedded microprocessor core that was synthesized and routed using industry standard CAD tools. Further, accurate models for TDDB, EM and NBTI were used to model the wearout related failures and determine the MTTFs for devices within the design. The results of these accelerated wearout experiments showed that most signals experience a sharply increasing latency when the breakdown period is entered. This recognition contributed to the design of the WDU. To enable the WDU to work in the presence of temperature variability, clock jitter and other environmental noise it uses statistical analysis hardware.

The WDU accurately detects and diagnoses wearout with a small area footprint: 4.45% of the OR1200 die area. The WDU was able to successfully detect the trends of increasing latency across multiple output signals for each module of the OpenRISC 1200 that was examined. These modules were then flagged as ailing before the point of failure. The achievable increase in the overall MTTF by incorporating WDUs and cold spare structures into the design is also described. With a an increase of 16.2% in the area, the MTTF increases by nearly 50%. A more substantial MTTF increase of approximately 150% can be obtained by 65% increase in the area.

The above description has included a discussion of
A thorough simulation infrastructure for modelling the physical effects of wearout on a synthesized, placed and routed implementation of a microprocessor core.
A self-calibrating WDU capable of statistically sampling and analyzing the signal propagation latencies through microarchitectural structures.
A demonstration of how processor life can be extended by deploying the WDU throughout the core to diagnose ailing structures, flagging them for replacement with cold spares.

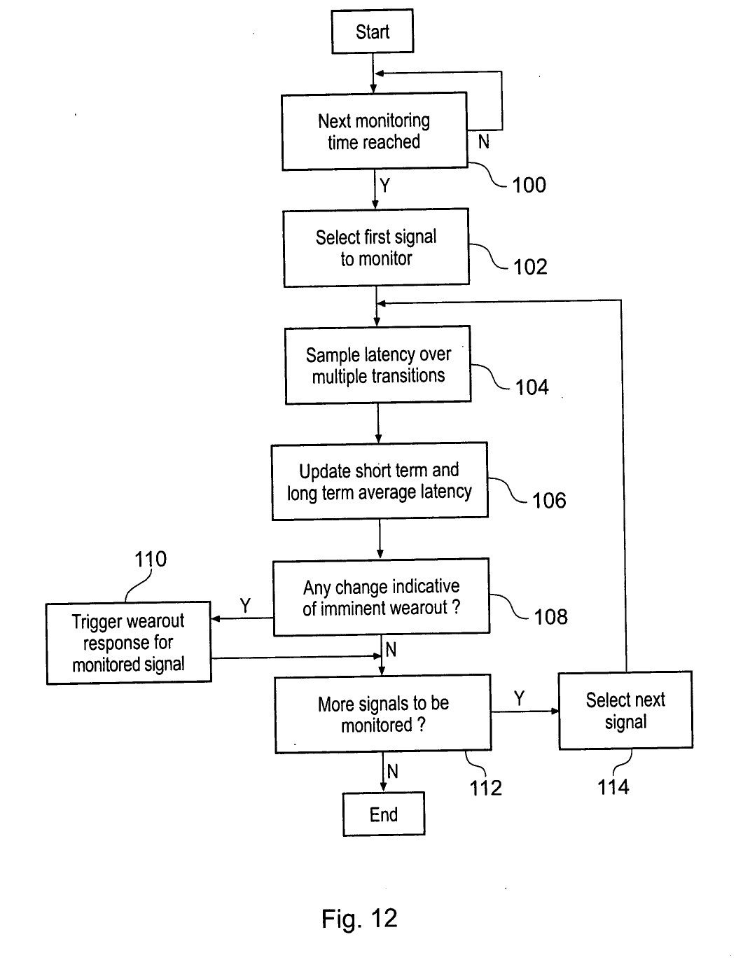

FIG. 12 is a flow diagram illustrating example processing which can be performed in a single wearout detection unit (latency detecting circuitry) to monitor a collection of signals within functional units of an integrated circuit (e.g. signals drawn from critical portions such as the instruction decoder, the ALU, a floating point unit, etc. At step 100 the wearout detection unit waits for the next time period to be reached at which monitoring is to be performed. Monitoring does not need to be very frequent as wearout processes are typically slow. As an example, monitoring could be performed daily, weekly or monthly. Monitoring at such widely spaced intervals makes the power consumption overhead associated with such monitoring and the processing involved negligible.

When the time for monitoring is reached then processing proceeds to step 102 at which the first signal to be monitored is selected. The wearout detection unit in this example can have the form illustrated in FIG. 9 as suited to monitor multiple signals.

At step 104 the latency associated with the signal transition being monitored is sampled over multiple transitions and then at step 106 the short term and long term average latency values are updated. Step 108 then determines whether there has been a change in either of these short term or long term average latency values which is indicative of imminent wearout within the circuitry (functional circuit) associated with the signal being monitored. If there has been such a change, then step 110 triggers a wearout response matched to the functional circuit concerned. If there has been no such change, then step 110 is bypassed.

Step 112 determines whether there are any more signals to be monitored in the current monitoring cycle. If there are such further signals then the next of these is selected at step 114 and processing is returned to step 104. If there are no further signals then processing terminates.

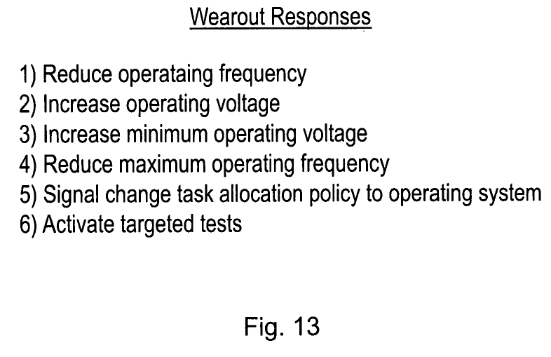

FIG. 13 illustrates various wearout responses which can be associated with different functional circuits. The typical ways in which a functional circuit may wear out can be known in advance in some circumstances and the appropriate wearout response then remapped to that circuit. Alternatively, when the functional circuit is operating in a plurality of different states (e.g. with different frequencies or different operating voltages), then it may be that wearout is only apparent in some of these states and different wearout responses may be appropriate in different circumstances. As an example, if a signal is failing its timing requirements due to an excessive latency when operating at the highest frequency in an operational range of frequencies, then reducing this highest frequency would likely extend the working life of the integrated circuit concerned. As an alternative, the same signal could in fact be subject to imminent wearout failure when operating at its lowest operating voltage within a range of operating voltage conditions and in such circumstances raising the minimum operating voltage would extend the circuit life.

In FIG. 13 the first two wearout responses are to reduce the operating frequency or increase the operating voltage. These can be applied to simple circuits in which a single operating frequency and operating voltage are employed. Responses 3 and 4 relate to systems having a range of operational voltages and a range of operating frequencies. In these circumstances failure can be addressed by increasing the minimum operating voltage and reducing the maximum operating frequency of the ranges concerned.

Wearout response 5 relates to multiprocessor systems in which wearout detected within one of the processors or one of the functional circuits within one of the processors can be used to influence the task allocation performed by the operating system controlling the multiprocessor system. As an example, if the wearout detection unit detects that the integer arithmetic or floating point unit within a particular processor is showing signs of imminent wearout then the operating system can serve to allocate tasks known to make intensive use of the integer arithmetic unit or floating point unit of a processor to other of the multiple processors so as to not force the processor subject to imminent wearout into actually exhibiting failure. This can extend the working life of the integrated circuit in a useful way. The operating system could allocate tasks to the imminently failing circuits when necessary at times of highest peak performance, but could otherwise allocate the tasks elsewhere so as to preserve the useful life of the functional circuit potentially subject to imminent wearout.

The sixth example wearout response in FIG. 13 is to activate targeted tests. In some safety critical systems it is known that these perform self-test operations at regular intervals. If a wearout detection unit detects a particular functional circuit as subject to imminent wearout, then additional testing can be directed to such a functional circuit to ensure that any failure that does occur is more rapidly detected and adverse consequences avoided.

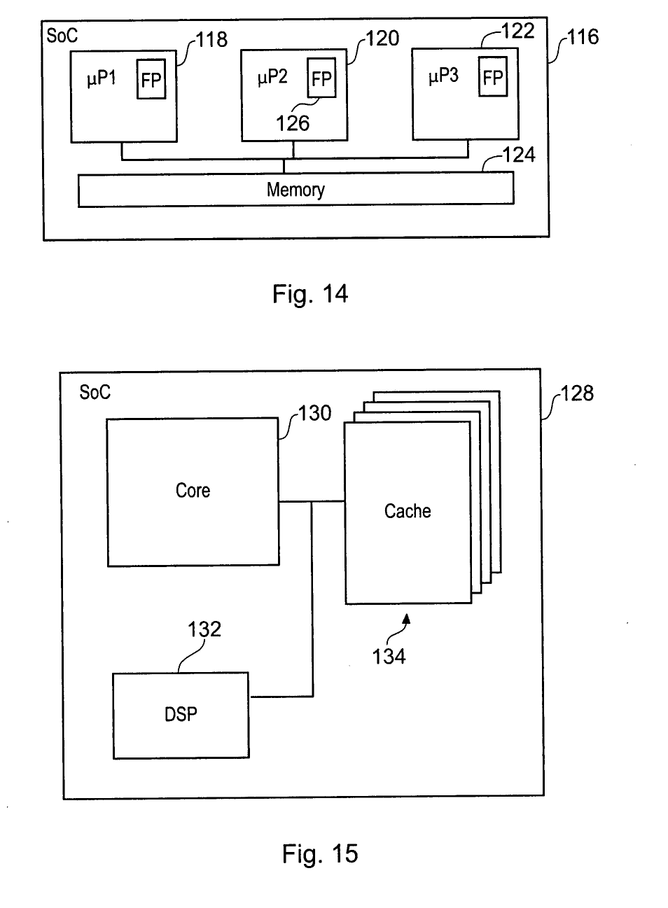

FIG. 14 schematically illustrates a multiprocessor integrated circuit 116 comprising multiple processor cores 118, 120 and 122 sharing a common memory 124. An operating system executing on one of the processors 118, 120 and 122 is responsible for task allocation between the processors 118, 120 and 122. If a wearout detection unit associated with one of the processors, for example with the floating point unit 126 within processor 120 indicates that imminent wearout is likely to occur, then the operating system can respond to this wearout indication by allocating floating point intensive processing to processor 118 and processor 122 rather than to processor 120. This can extend the useful working life of the integrated circuit 116.

FIG. 15 illustrates an integrated circuit 128 incorporating a processor core 130, a digital signal processor 132 and a cache memory 134. The cache memory comprises multiple banks of memory to provide a large cache memory capability. When the integrated circuit 128 is manufactured then it will typically be subject to manufacturing test operations in order to check that it is correctly formed. As will be known to those in this technical field it is usual for a certain percentage of integrated circuits to fail for some reason to be formed properly. In order to identify such defective integrated circuits test vectors are typically applied and data written into and out of memory so as to check that the integrated circuit 128 functions as intended. The wearout detection units of the present technique can be used as part of this manufacturing test to determine the signal latencies of the signals being monitored within the integrated circuit 128. This will give an indication as to the margin for deterioration due to wearout that is present within the integrated circuit 128 under test. Certain individual integrated circuits may be formed exactly in accordance with the intended design and have a large margin for deterioration due to wearout and accordingly a long potential life. This can be detected by the wearout units and the wearout response associated therewith can be to classify such individual integrated circuits 128 as long life circuits due to their anticipated high resistance to wearout. Such integrated circuits could be sold for a premium price. Other individual integrated circuits when tested may be shown to be operational but have very little margin for deterioration due to wearout. Such integrated circuits could still be sold but as non-premium products and potentially targeted to non-critical applications.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

### REFERENCES

Openrisc 1200, 2006.
http://www.opencores.org/projects.cgi/web/orlk/openrisc1200.
[2] Reliability in cmos ic disign: Physical failure mechanisms and their modelling, 2006.
[3] Ridgetop group, 2006. http://www.ridetop-group.com/.
[4] A. I. Abou-Seido, B. Nowak, and C. Chu. Fitted elmore delay: A simple and accurate interconnect delay model. IEEE Transactions on Very Large Scale Integration (VLSI) Systems, 12(7):691-696, July 2004.
[5] J. S. S. T. Association. Failure mechanisms and models for semiconductor devices. Technical Report JEPI22C, JEDEC Solid State Technology Association, March 2006.
[6] T. Austin. Diva: a reliable substrate for deep submicron microarchitecture design. In Proc. of the 32nd Annual International Symposium on Microarchitecture, pages 196-207, 1999.
[7] T. Austin, D. Blaauw, T. Mudge, and K. Flautner. Making typical silicon matter with razor. IEEE Computer, 37(3):57-65, March 2004.
[8] A. Avellan and W. H. Krautschneider. Impact of soft and hard breakdown on analog and digital circuits. IEEE Transactions on Device and Materials Reliability, 4(4):676-680, December 2004.
[9] M. Batty. Monitoring an exponential smoothing forecasting system. Operational Research Quaterly, 20(3):319-325, 1969.
[10] D. Bernick, B. Bruckert, P. D. Vigna, D. Garcia, R. Jardine, J. Klecka, and J. Smullen. Nonstop Advanced Architecture. In International Conference on Dependable Systems and Networks, pages 12-21, June 2005.
[11] S. Borkar. Designing reliable systems from unreliable components: The challenges of transistor variability and degradation. IEEE Micro, 25(6):10-16, 2005.
[12] F. A. Bower, D. J. Sorin, and S. Ozev. A mechanism for online diagnosis of hard faults in microprocessors. In Proc. of the 38th Annual International Symposium on Microarchitecture, pages 197-208, 2005.
[13] A. Christou. Electromigration and Electronic Device Degradation. John Wiley and Sons, Inc., 1994.
[14] D. Dumin. Oxide Reliability: A Summary of Silicon Oxide Wearout, Breakdown, and Reliability. World Scientific Publishing Co. Pte. Ltd., 2002.
[15] W. C. Elmore. The transient response of damped linear network with particular regard to wideband amplifiers. Journal of Applied Physics, 19(1):55-63, January 1948.
[16] M. Gomaa and T. Vijaykumar. Opportunistic transient-fault detection. In Proc. of the 32nd Annual International Symposium on Computer Architecture, pages 172-183, June 2005.
[17] C.-K. Hu et al. Effects of overlayers on electromigration reliability improvement for cu/low k interconnects. In Proc. of the 2004 International Reliability Physics Symposium, pages 222-228, April 2004.
[18] T. Kehl. Hardware self-tuning and circuit performance monitoring. In Proc. of the 1993 International Conference on Computer Design, pages 188-192, October 1993.
[19] E. Ogawa. Electromigration reliability issues in dual-damascene cu interconnections. IEEE Transactions on Reliability, 51(4):403-419, December 2002.
[20] J. Ray, J. Hoe, and B. Falsafi. Dual use of superscalar datapath for transient-fault detection and recovery. In Proc. of the 34th Annual International Symposium on Microarchitecture, pages 214-224, December 2001.
[21] V. Reddy, S. Parthasarathy, and E. Rotenberg. Understanding prediction-based partial redundant threading for low-overhead, high-coverage fault tolerance. In 14th International Conference on Architectural Support for Programming Languages and Operating Systems, pages 83-94, October 2006.
[22] S. K. Reinhardt and S. S. Mukherjee. Transient fault detection via simultaneous multithreading. In Proc. of the 27th Annual International Symposium on Computer Architecture, pages 25-36, June 2000.
[23] G. Reis, J. Chang, N. Vachharajani, R. Rangan, and D. I. August. SWIFT: Software implemented fault tolerance. In Proc. of the 2005 International Symposium on Code Generation and Optimization, pages 243-254, 2005.
[24] E. Rotenberg. AR-SMT: A microarchitectural approach to fault tolerance in microprocessors. In International Symposium on Fault Tolerant Computing, pages 84-91, 1999.
[25] P. Shivakumar, S. Keckler, C. Moore, and D. Burger. Exploiting microarchitectural redundancy for defect tolerance. In Proc. of the 2003 International Conference on Computer Design, October 2003.
[26] M. L. Shooman. Probabilistic Reliability: An Engineering Approach. Robert E. Krieger Publishing Company, 1990.
[27] K. Skadron, M. R. Stan, K. Sankaranarayanan, W. Huang, S. Velusamy, and D. Tarjan. Temperature-aware microarchitecture: Modelling and implementation. ACM Transactions on Architecture and Code Optimization, 1(1):94-125, 2004.
[28] J. Smolens, J. Kim, J. Hoe, and B. Falsafi. Efficient resource sharing in concurrent error detecting superscalar microarchitectures. In Proc. of the 37th Annual International Symposium on Microarchitecture, pages 256-268, December 2004.
[29] A. Sodani and G. Sohi. Dynamic instruction reuse. In Proc. of the 25th Annual International Symposium on Computer Architecture, pages 194-205, June 1998.
[30] P. Solomon. Breakdown in silicon oxide—a review. Journal of Vacuum Science and Technology, 14(5): 1122-1130, September 1977.
[31] L. Spainhower and T. Gregg. IBM S/3 90 Parallel Enterprise Server G5 Fault Tolerance: A Historical Perspective. IBM Journal of Research and Development, 43(6):863-873, 1999.
[32] J. Srinivasan, S. V. Adve, P. Bose, and J. A. Rivers. The case for lifetime reliability-aware microprocessors. In Proc. of the 31st Annual International Symposium on Computer Architecture, pages 276-287, June 2004.
[33] J. Srinivasan, S. V. Adve, P. Bose, and J. A. Rivers. Exploiting structural duplication for lifetime reliability enhancement. In Proc. of the 32nd Annual International Symposium on Computer Architecture, pages 520-531, June 2005.
[34] StockCharts.com. TRIX, October 2006. http://stockcharts.com/education/IndicatorAnalysis/indictrix.htm.
[35] T. Vijaykumar, I. Pomeranz, and K. Cheng. Transient-fault recovery via simultaneous multithreading. In Proc. of the 29th Annual International Symposium on Computer Architecture, pages 87-98, May 2002.
[36] N. Wang and S. Patel. Restore: Symptom based soft error detection in microprocessors. In International Conference on Dependable Systems and Networks, pages 30-39, June 2005.
[37] E. Wu et al. Interplay of voltage and temperature acceleration of oxide breakdown for ultra-thin gate oxides. Solid-State Electronics, 46:1787-1798, 2002.
[38] T. J. Yamaguchi, M. Soma, D. Halter, J. Nissen, R. Raina, M. Ishida, and T. Watanabe. Jitter measurements of a powerpc microprocessor using an analytic signal method. In Proc. of the 2000 International Test Conference, pages 955-964, 2000.
[39] S. Zafar et al. A model for negative bias temperature instability (nbti) in oxide and high k pfets. In Symposium on VLSI Technology, pages 45-50, 2004.

We claim:

1. A method of detecting wearout of an integrated circuit having at least one functional circuit, said method comprising:
detecting signal generation latency of at least one signal within a functional circuit; and
in response to said signal generation latency, triggering a wearout response.

2. A method as claimed in claim 1, wherein said wearout response is triggered in response to an increase in said signal generation latency and before failure due to wearout occurs.

3. A method as claimed in claim 1, wherein
said detecting includes averaging said signal generation latency over time to generate an averaged signal generation latency; and
said triggering is responsive to said averaged signal generation latency.

4. A method as claimed in claim 3, wherein said averaging comprises generating at least a short term average and a long term average.

5. A method as claims in claim 3, wherein said averaging comprises triple smooth exponential moving averaging.

6. A method as claimed in claim 1, wherein said triggering comprises comparing said signal generation latency for a predetermined set of vectors with a predetermined threshold value.

7. A method as claimed in claim 1, wherein said wearout response comprises reducing an operating frequency of said integrated circuit.

8. A method as claimed in claim 1, wherein said wearout response comprises increasing an operating voltage of said integrated circuit.

9. A method as claimed in claim 1, wherein said wearout response comprises decreasing an operating voltage range of said integrated circuit.

10. A method as claimed in claim 1, wherein said integrated circuit comprises a plurality of processing units, said detecting detects wearout in one of said plurality of processing units and said wearout response comprises redistributing task allocation between said plurality of processing units to reduce use of said one of said plurality of processing units at least in respects of said functional unit in which wearout has been detected.

11. A method as claimed in claim 1, wherein said method is performed as part of manufacturing test operations and said wearout response comprises binning said integrated circuits in dependence upon detected susceptibility to wearout.

12. A method as claimed in claim 1, wherein said wearout response comprises applying self test operations targeted at a function unit in which wearout has been detected as increasing.

13. A method as claimed in claim 1, wherein said detecting is performed by comparing occurrence of a transition of a signal within said functional circuit with occurrence of respective transitions in a plurality of reference signals having respective predetermined reference timings.

14. A method as claimed in claim 13, wherein said plurality of reference signals are generated by a plurality of taps from a delay line.

15. An integrated circuit comprising:
at least one functional circuit;
latency detecting circuitry responsive to at least one signal within a functional circuit to detect signal generation latency; and
wearout response triggering circuitry coupled to latency detecting circuitry and responsive to said signal generation latency to trigger a wearout response.

16. An integrated circuit as claimed in claim 15, wherein said wearout response is triggered in response to an increase in said signal generation latency and before failure due to wearout occurs.

17. An integrated circuit as claimed in claim 15, wherein
said latency detecting circuitry averages said signal generation latency over time to generate an averaged signal generation latency; and
wearout response triggering circuitry is responsive to said averaged signal generation latency.

18. An integrated circuit as claimed in claim 17, wherein said averaging comprises generating at least a short term average and a long term average.

19. An integrated circuit as claims in claim 17, wherein said averaging comprises triple smooth exponential moving averaging.

20. An integrated circuit as claimed in claim 15, wherein said wearout response triggering circuitry compares said signal generation latency for a predetermined set of vectors with a predetermined threshold value.

21. An integrated circuit as claimed in claim 15, wherein said wearout response comprises reducing an operating frequency of said integrated circuit.

22. An integrated circuit as claimed in claim 15, wherein said wearout response comprises increasing an operating voltage of said integrated circuit.

23. An integrated circuit as claimed in claim 15, wherein said wearout response comprises decreasing an operating voltage range of said integrated circuit.

24. An integrated circuit as claimed in claim 15, comprising a plurality of processing units, wherein said latency detecting circuitry detects wearout in one of said plurality of processing units and said wearout response comprises redistributing task allocation between said plurality of processing units to reduce use of said one of said plurality of processing units at least in respect of said functional unit in which wearout has been detected.

25. An integrated circuit as claimed in claim 15, wherein said latency detecting circuitry operates during manufacturing test operations and said wearout response comprises binning said integrated circuits in dependence upon detected susceptibility to wearout.

26. An integrated circuit as claimed in claim 15, wherein said wearout response comprises applying self test operations targeted at a function unit in which wearout has been detected.

27. An integrated circuit as claimed in claim 15, wherein said latency detecting circuitry includes comparison circuitry responsive to occurrence of a transition of a signal within said functional circuit and occurrence of respective transitions in a plurality of reference signals having respective predetermined reference timings.

28. An integrated circuit as claimed in claim 27, wherein said plurality of reference signals are generated by a plurality of taps from a delay line.

29. An integrated circuit comprising:
at least one functional circuit means;
latency detecting means for detecting signal generation latency in at least one signal within a functional circuit; and
wearout response triggering means coupled to said latency detecting circuitry for trigger a wearout response in response to said signal generation latency.
